(19) United States
(12) Patent Application Publication
(10) Pub. No.: US 2026/0175440 A1
(43) Pub. Date: Jun. 25, 2026

(54) SUBSTRATE TRANSFER SYSTEM AND SUBSTRATE TRANSFER METHOD

(71) Applicant: SCREEN Holdings Co., Ltd., Kyoto (JP)

(72) Inventors: Ryo MORIZUMI, Kyoto (JP); Genki TOMODA, Kyoto (JP); Hiroyuki KAWAHARA, Kyoto (JP)

(21) Appl. No.: 19/424,113

(22) Filed: Dec. 17, 2025

(30) Foreign Application Priority Data
Dec. 20, 2024 (JP) 2024-225691

(51) Int. Cl. B25J 11/00; B25J 13/08; B25J 15/00; H10P 72/00; H10P 72/76

(52) U.S. Cl. CPC B25J 11/0095; B25J 13/088; B25J 15/0014; B25J 15/0052; H10P 72/0608; H10P 72/7602

(57) ABSTRACT

A substrate transfer system capable of optimizing a hand pitch in accordance with an arrangement state of a plurality of substrates. A substrate processing apparatus (1) includes: a substrate transfer mechanism (IR) including a plurality of hands and an inter-hand pitch adjustment section that adjusts each inter-hand pitch, which is a pitch between the plurality of hands; and a controller (71), the controller controlling the inter-hand pitch adjustment section so that the plurality of hands respectively enter a plurality of hand entry positions which have been calculated on the basis of an arrangement state of the plurality of substrates.

This Nonprovisional application claims priority under 35 U.S.C. § 119 on Patent Application No. 2024-225691 filed in Japan on Dec. 20, 2024, the entire contents of which are hereby incorporated by reference.

### TECHNICAL FIELD

The present invention relates to a substrate transfer system and a substrate transfer method in the substrate transfer system.

### BACKGROUND ART

Conventionally, a substrate holding apparatus has been known that, for example, in a processing step for a semiconductor or the like, takes out substrates such as silicon wafers from a transfer container in which the substrates are accommodated so as to be arranged at a predetermined pitch in a thickness direction of the substrates and transfers the substrate. As such a substrate holding apparatus, a substrate holding apparatus that includes a plurality of substrate holders each capable of holding a substrate and that can hold a plurality of substrates may be used. In this case, it is considered necessary to adjust an interval between the substrate holders in accordance with an arrangement state of the plurality of substrates. Patent Literature 1 discloses a substrate holding apparatus which includes a support mechanism that changes a pitch between a plurality of substrate holders. The support mechanism includes the same number of support bases as the substrate holders, a pair of guide rails, a rotating member, and a pitch change drive section.

### CITATION LIST

### Patent Literature

[Patent Literature 1]

Japanese Patent Application Publication Tokukai No. 2013-135099

### SUMMARY OF INVENTION

### Technical Problem

However, in the substrate holding apparatus disclosed in Patent Literature 1, the plurality of substrate holders are always arranged at equal intervals. For this reason, it has not been possible to sufficiently optimize the pitch in a case where an optimal pitch corresponding to the arrangement state of the plurality of substrates is not constant.

An object of an aspect of the present invention is to provide a substrate transfer system and the like that can optimize a hand pitch in accordance with an arrangement state of a plurality of substrates.

### Solution to Problem

In order to solve the above problem, a substrate transfer system according to an aspect of the present invention includes: a substrate transfer mechanism including a plurality of hands for taking out a plurality of substrates from a transfer container which carries the plurality of substrates during transfer, in a state in which the plurality of substrates are accommodated in a shelf-like manner, and an inter-hand pitch adjustment section that adjusts each inter-hand pitch, which is a pitch between the plurality of hands; a substrate detection section that detects an arrangement state of the plurality of substrates in the transfer container; and a controller, said substrate transfer system taking out the plurality of substrates from the transfer container and transferring the plurality of substrates, by the substrate transfer mechanism, the controller calculating a plurality of hand entry positions which the hands are caused to enter, on the basis of the arrangement state of the plurality of substrates that is detected by the substrate detection section, and the controller controlling the inter-hand pitch adjustment section so that the plurality of hands provided in the substrate transfer mechanism respectively enter the plurality of hand entry positions.

Further, a substrate transfer method according to an aspect of the present invention is a method for a substrate transfer system, the substrate transfer system including: a substrate transfer mechanism including a plurality of hands for taking out a plurality of substrates in a transfer container which carries the plurality of substrates during transfer, in a state in which the plurality of substrates are accommodated in a shelf-like manner, and an inter-hand pitch adjustment section that adjusts each inter-hand pitch, which is a pitch between the plurality of hands; and a substrate detection section that detects an arrangement state of the plurality of substrates in the transfer container, the substrate transfer system taking out the plurality of substrates from the transfer container and transferring the plurality of substrates, by the substrate transfer mechanism, said substrate transfer method including: calculating hand entry positions which the hands are caused to enter, on the basis of the arrangement state of the plurality of substrates that is detected by the substrate detection section; and controlling the inter-hand pitch adjustment section so that the plurality of hands provided in the substrate transfer mechanism respectively enter the hand entry positions.

### Advantageous Effects of Invention

An aspect of the present invention can provide a substrate transfer system and the like that can optimize a hand pitch in accordance with an arrangement state of a plurality of substrates.

### BRIEF DESCRIPTION OF DRAWINGS

FIG. 1 is a plan view illustrating a substrate processing apparatus according to an example.

FIG. 2 is a lateral cross sectional view of a carrier.

FIG. 3 is a front view of the carrier.

FIG. 4 is a vertical cross sectional view illustrating the substrate processing apparatus according to the example.

FIG. 5 is a side view illustrating a lid attachment/detachment section.

FIG. 6 is a plan view illustrating mapping sensors located at standby positions.

FIG. 7 is a plan view illustrating the mapping sensors located at detection positions.

FIG. 8 is a side view of hands.

FIG. 9 is a front view of inter-hand pitch adjustment sections.

FIG. 10 is a side view of the inter-hand pitch adjustment sections.

FIG. 11 is a diagram illustrating an example of a method for calculating a hand entry position.

FIG. 12 is a diagram illustrating an example operation of a transfer robot.

FIG. 13 is a flowchart showing an example of a substrate transfer method.

FIG. 14 is a flowchart showing an example of a calibration process.

### DESCRIPTION OF EMBODIMENTS

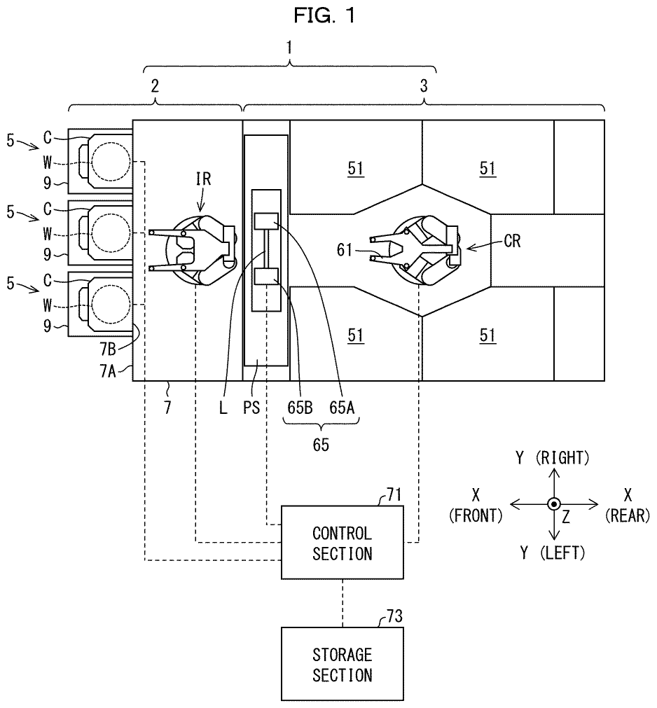

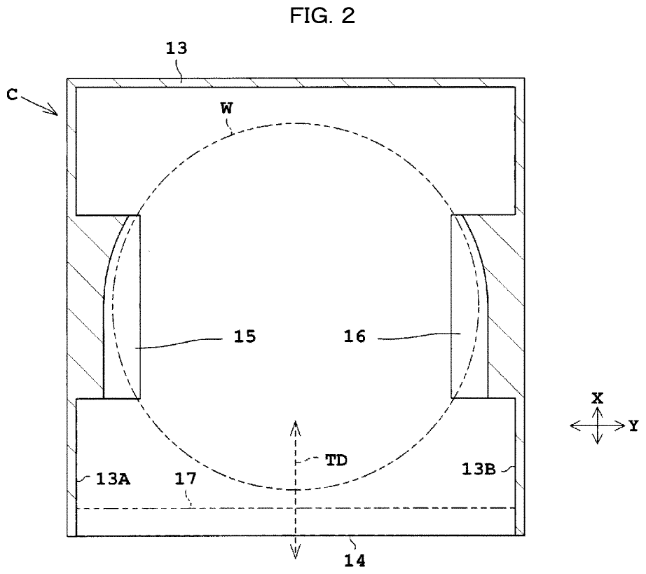

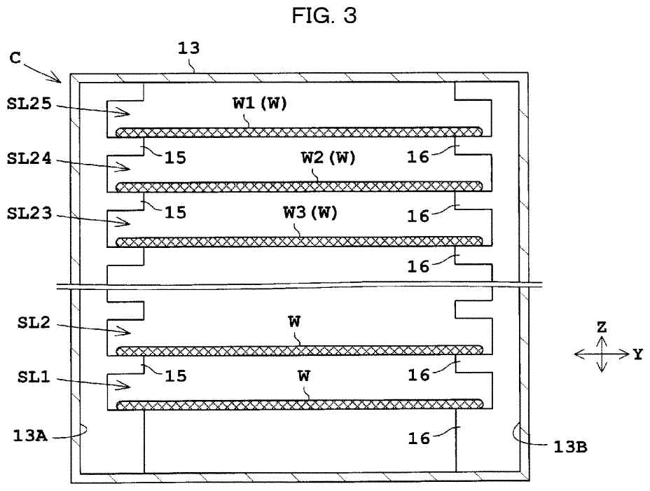

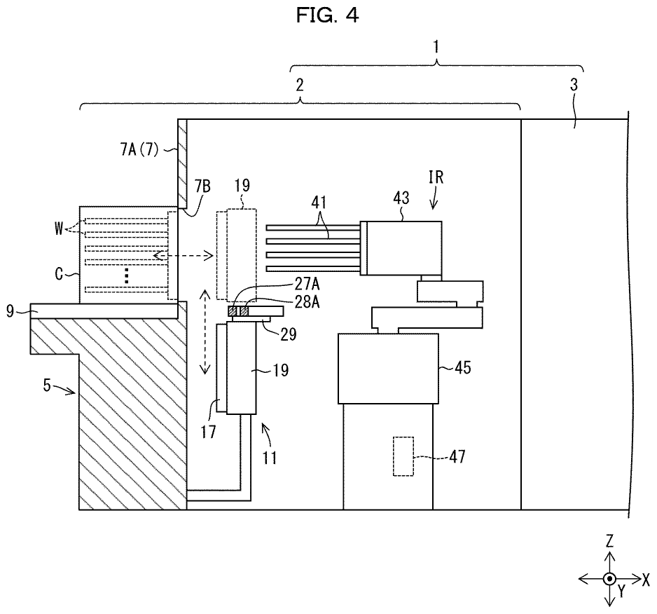

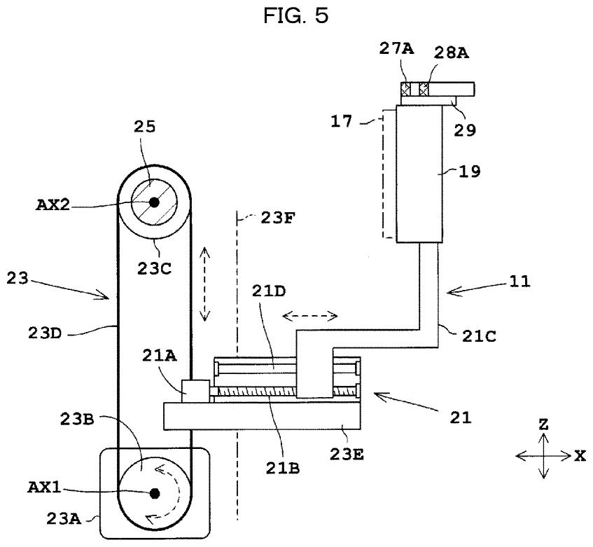

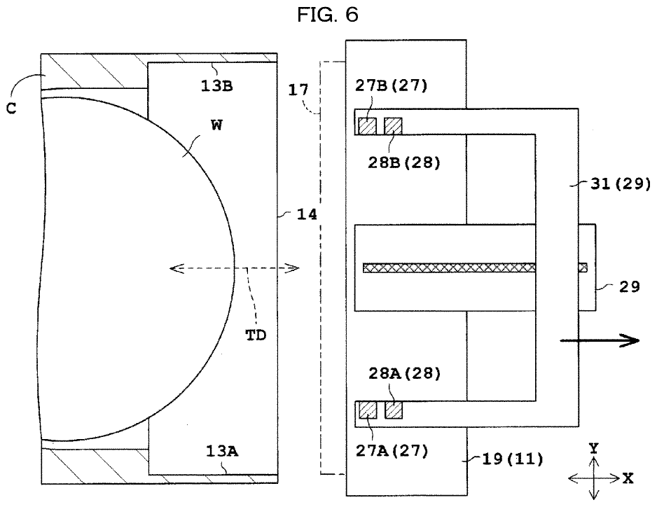

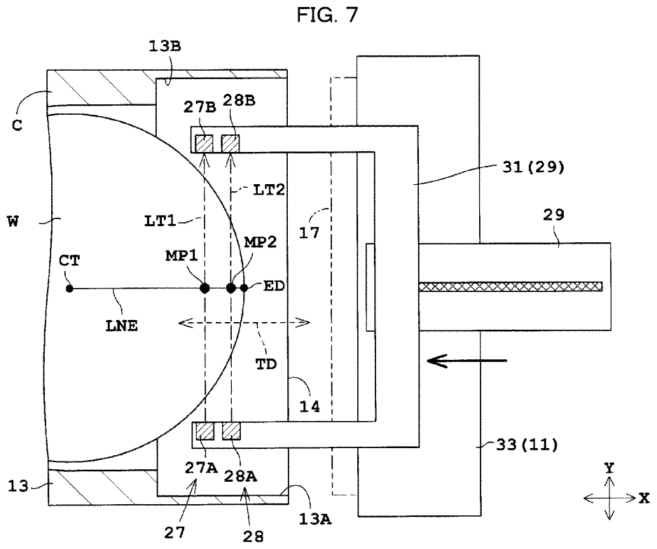

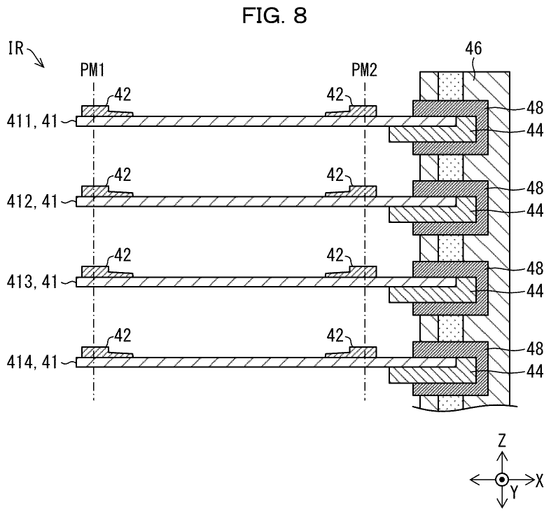

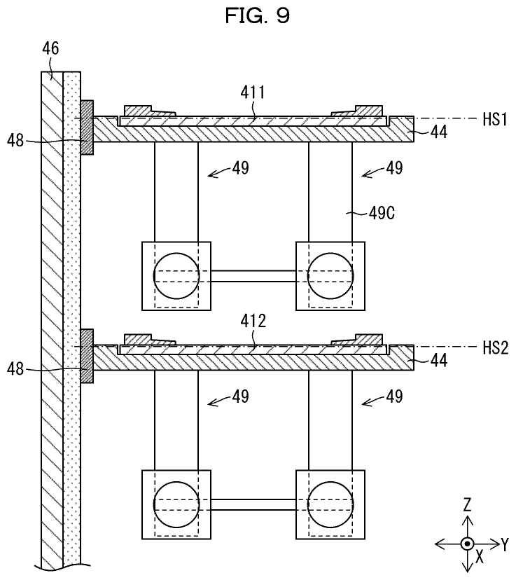

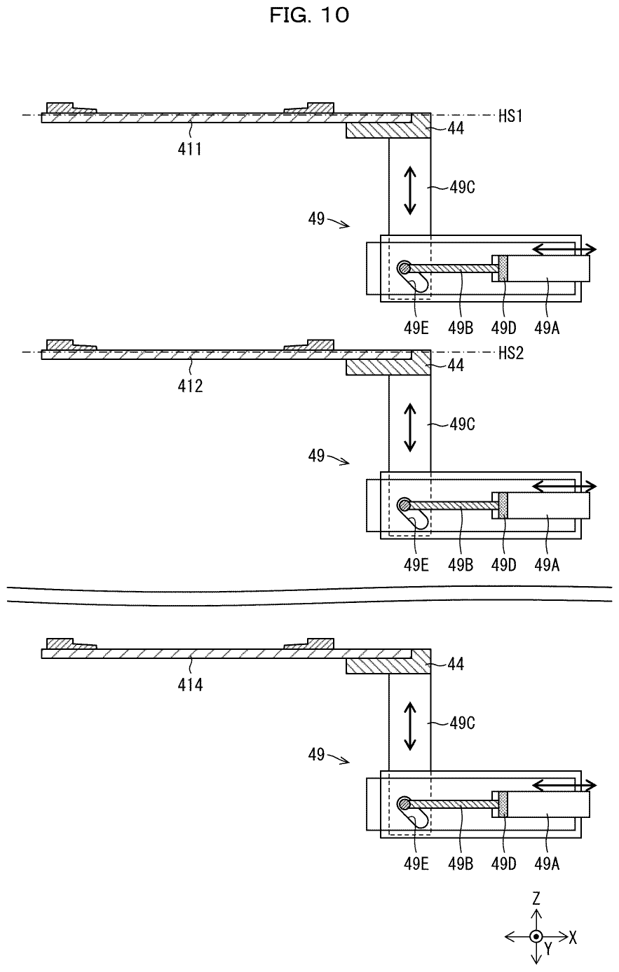

The following description will discuss Example 1 of the present invention with reference to the drawings. FIG. 1 is a plan view illustrating a substrate processing apparatus 1 (substrate transfer system) according to the example. FIG. 2 is a lateral cross sectional view of a carrier C. FIG. 3 is a front view of the carrier C. FIG. 4 is a vertical cross sectional view illustrating the substrate processing apparatus 1 according to the example. FIG. 5 is a side view illustrating a lid attachment/detachment section 11. FIG. 6 is a plan view illustrating mapping sensors 27 and 28 located at standby positions. FIG. 7 is a plan view illustrating the mapping sensors 27 and 28 located at detection positions. FIG. 8 is a side view of hands 41. FIG. 9 is a front view of inter-hand pitch adjustment sections 49. FIG. 10 is a side view of the inter-hand pitch adjustment sections 49.

### 1. Configuration of Substrate Processing Apparatus

Reference is made to FIG. 1. The substrate processing apparatus 1 processes substrates W. The substrate processing apparatus 1 includes an indexer block 2 and a processing block 3.

Note that a horizontal direction in which the indexer block 2 and the processing block 3 are arranged is referred to as a front-rear direction (X direction). A direction from the processing block 3 to the indexer block 2 is referred to as a forward direction, and a direction reverse to the forward direction is a rearward direction. Further, a horizontal direction that is orthogonal to the front-rear direction is referred to as a width direction (Y direction). A direction that is orthogonal to the front-rear direction and the width direction is referred to as a vertical direction (Z direction).

### 1-1. Indexer Block

The indexer block 2 includes one or more (three in FIG. 1) load ports (openers) 5, a housing 7, and a transfer robot IR (substrate transfer mechanism). The load ports 5 are used for loading and unloading the substrate W. Each of the load ports 5 is provided with a stage 9 and a lid attachment/detachment section 11 (see FIG. 4). A carrier C (transfer container) is placed on the stage 9.

The load ports 5 each further include a load presence sensor (not illustrated) that detects placement of a carrier C when the carrier C is placed on the stage 9. The indexer block 2 detects that a carrier C is placed on the stage 9 by the load presence sensor, and takes out substrates W from the carrier C and transfers the substrates W, by the transfer robot IR.

The carrier C carries a plurality of substrates W in a state in which the substrates are accommodated in a shelf-like manner during transfer. In terms of design, the carrier C accommodates the plurality of (e.g., 25) substrates W in the horizontal orientation, which are aligned in the vertical direction (Z direction) at a predetermined pitch (e.g., a 10 mm pitch). The substrates W are each formed, for example, in a disk shape. As the carrier C, for example, a front-opening unified pod (FOUP) is used, but the carrier C is not limited thereto. For example, the carrier C may be a cassette (open cassette) that does not have a lid part 17 (described later) for closing an opening 14 (described later).

Reference is made to FIGS. 2 and 3. The carrier C includes a container (carrier body) 13, the opening 14, a plurality of pairs (e.g., 25 pairs) of shelf parts 15 and 16, and the lid part 17. The container 13 accommodates a plurality of substrates W. The opening 14 is provided on a front side of the container 13. Each of the plurality of substrates W is taken out from the carrier C through the opening 14 and accommodated in the carrier C through the opening 14. When the carrier C is transferred, the lid part 17 that closes the opening 14 is attached to the container 13. On the other hand, when the substrates W are taken out from the carrier C, the lid part 17 is detached from the container 13.

A plurality of pairs of shelf parts 15 and 16 are provided in the vertical direction in the container 13. In the vertical direction, in terms of design, the plurality of pairs of shelf parts 15 and 16 are arranged at a predetermined pitch (e.g., a pitch of 10 mm). One substrate W is placed in the horizontal orientation on each pair of the shelf parts 15 and 16. As illustrated in FIG. 3, for example, 25 shelf parts 15 are provided on a left inner wall 13A of the container 13, and 25 shelf portions 16 are provided on a right inner wall 13B of the container 13.

Further, in the carrier C, for example, a space for accommodating one substrate W between two vertically adjacent pairs of shelf parts 15 and 16 is called a slot. Therefore, the carrier C includes a plurality of (e.g., 25) slots SL1 to SL25 for respectively accommodating a plurality of (e.g., 25) substrates W. The 25 slots SL1 to SL25 are arranged in order from bottom to top. The slot SL1 is at the lowest position, and the slot SL25 is at the highest position.

The plurality of load ports 5 are arranged in the width direction (Y direction). The plurality of load ports 5 are provided at a front part of the indexer block 2. Specifically, three load ports 5 are provided on a front wall portion 7A of the housing 7 on the outside of the housing 7. The wall portion 7A is provided with a passage opening 7B that corresponds to the opening 14 of the carrier C which is placed on the stage 9 of each of the load ports 5. For example, the transfer robot IR takes out, through the passage opening 7B, the substrates W from the carrier C which is placed on the stage 9. For simplicity, in FIG. 1, only the passage opening 7B corresponding to one stage 9 is denoted by a reference sign.

The lid attachment/detachment section 11 of the load port 5 includes a shutter section 19, a shutter advancing/retreating section 21, a shutter lifting/lowering section 23, and a rotary encoder (height sensor) 25. The shutter section 19 opens and closes a corresponding passage opening 7B. Further, the shutter section 19 can hold the lid part 17 of the carrier C. Therefore, the shutter section 19 can detach the lid part 17 from the carrier C and attach the lid part 17 to the carrier C.

The shutter advancing/retreating section 21 advances and retreats the shutter section 19 in the front-rear direction (X direction). The shutter advancing/retreating section 21 includes, for example, an electric motor 21A, a screw shaft 21B, a slider 21C, and a guide rail 21D. The shutter advancing/retreating section 21 may include an air cylinder instead of the electric motor 21A, the screw shaft 21B, and the like. The slider 21C supports the shutter section 19.

The shutter lifting/lowering section 23 moves the shutter section 19, two light projecting sections 27A and 28A (described later), two light receiving sections 27B and 28B (described later), and a sensor support member 31 (described later) in the vertical direction (Z direction). The shutter lifting/lowering section 23 includes, for example, an electric motor 23A, two pulleys 23B and 23C, a timing belt 23D, a slider 23E, and a guide rail 23F.

The two pulleys 23B and 23C are arranged in the vertical direction. The two pulleys 23B and 23C are supported so as to be rotatable around two horizontal axes AX1 and AX2, respectively. The two horizontal axes AX1 and AX2 each extend, for example, in the width direction (Y direction). A ring-shaped timing belt 23D is wound around the two pulleys 23B and 23C. Further, the slider 23E is attached (fixed) to the timing belt 23D. The guide rail 23F is arranged to extend in the vertical direction. The slider 23E is guided in the vertical direction by the guide rail 23F. The slider 23E supports the shutter advancing/retreating section 21.

A rotational output shaft of the electric motor 23A is connected to, for example, the pulley 23B on a lower side. The electric motor 23A rotates the pulley 23B around the horizontal axis AX1. In a case where the pulley 23B on the lower side is rotated, the pulley 23C on an upper side is rotated around the horizontal axis AX2 by the timing belt 23D. In a case where the electric motor 23A rotates the pulley 23B in a positive direction, the slider 23E, the shutter advancing/retreating section 21, the shutter section 19, the two light projecting sections 27A and 28A, and the two light receiving sections 27B and 28B ascend together with movement of the timing belt 23D. In contrast, in a case where the electric motor 23A rotates the pulley 23B in a reverse direction, the slider 23E, the two light projecting sections 27A and 28A, and the two light receiving sections 27B and 28B, and the like descend together with the movement of the timing belt 23D.

The rotary encoder 25 measures respective height positions of the shutter section 19 and the two mapping sensors 27 and 28 (the light projecting sections 27A and 28A and the light receiving sections 27B and 28B). The rotary encoder 25 is connected to, for example, the pulley 23C on the upper side. The rotary encoder 25 detects a mechanical displacement amount of rotation of the pulley 23C, and outputs the mechanical displacement amount as a pulse (pulse signal). By counting the number of pulses from the rotary encoder 25, a movement amount in the vertical direction of, for example, the shutter section 19, the light projecting sections 27A and 28A, and the light receiving sections 27B and 28B are acquired. Furthermore, the height positions of the shutter section 19, the light projecting sections 27A and 28A, and the light receiving sections 27B and 28B from a reference position are acquired.

Note that the rotational output shaft of the electric motor 23A may be connected to the pulley 23C on the upper side instead of the pulley 23B on the lower side. Further, the rotary encoder 25 may be connected to the pulley 23B on the lower side, instead of the pulley 23C on the upper side, so as to detect the mechanical displacement amount of rotation of the pulley 23B on the lower side. Further, in a case where the rotational output shaft of the electric motor 23A is connected to the pulley 23B on the lower side, the rotary encoder 25 may be connected to the pulley 23B on the lower side. In addition, instead of the rotary encoder 25, a linear encoder may be provided as the height sensor.

Reference is made to FIGS. 6 and 7. The load port 5 further includes two mapping sensors 27 and 28 (substrate detection sections) and a sensor moving section 29.

The first mapping sensor 27 and the second mapping sensor 28 are used to detect the arrangement state of the substrates W in the carrier C. The first mapping sensor 27 includes the light projecting section 27A and the light receiving section 27B. Similarly, the second mapping sensor 28 includes the light projecting section 28A and the light receiving section 28B.

As each of the mapping sensors 27 and 28, for example, a through-beam fiber sensor is used. For example, the first mapping sensor 27 further includes a light projecting element (e.g., light emitting diode, that is, LED), a light receiving element, a first optical fiber, and a second optical fiber. The first optical fiber sends light from the light projecting element to the light projecting section 27A. The second optical fiber sends, to the light receiving element, the light that has been received by the light receiving section 27B. The light receiving element converts, into an electrical signal, the light which has been received. The first mapping sensor 27 outputs a signal corresponding to an amount of light (intensity of received light) that has been received by the light receiving section 27B. The second mapping sensor 28 is configured similarly to the first mapping sensor 27.

The light projecting sections 27A and 28A and the light receiving sections 27B and 28B are provided, for example, on an upper surface of the shutter section 19 via the sensor moving section 29. The sensor moving section 29 includes a sensor support member 31. The sensor support member 31 is formed so as to have, for example, a C-shape in plan view. The sensor support member 31 supports the two mapping sensors 27 and 28 (the two light projecting sections 27A and 28A and the two light receiving sections 27B and 28B).

The two light projecting sections 27A and 28A are provided at a first end portion of the sensor support member 31 that has a C-shape. Further, the two light receiving sections 27B and 28B are provided at a second end portion of the sensor support member 31. The light projecting sections 27A and 28A and the light receiving sections 27B and 28B are arranged at the same height position.

The light projecting section 27A and the light receiving section 27B of the first mapping sensor 27 are arranged in the width direction (Y direction). Similarly, the light projecting section 28A and the light receiving section 28B of the second mapping sensor 28 are arranged in the width direction. The width direction is a horizontal direction orthogonal to a loading/unloading direction TD (FIGS. 6 and 7) in which a plurality of substrates W are loaded into and unloaded from the carrier C through the opening 14 of the carrier C.

The light projecting section 27A and the light receiving section 27B of the first mapping sensor 27 face each other. In a case where there is no obstacle that blocks light, light that has been emitted from the light projecting section 27A is received by the light receiving section 27B. An optical axis LT1 connecting the light projecting section 27A and the light receiving section 27B extends in the width direction (Y direction).

Similarly, the light projecting section 28A and the light receiving section 28B of the second mapping sensor 28 face each other. In a case where there is no obstacle that blocks light, light that has been emitted from the light projecting section 28A is received by the light receiving section 28B. An optical axis LT2 connecting the light projecting section 28 A and the light receiving section 28B extends in the width direction.

The sensor moving section 29 further includes, for example, an electric motor, a screw shaft, a guide rail, and a slider. The sensor moving section 29 may include an air cylinder, instead of the above components. The sensor moving section 29 linearly moves the two light projecting sections 27A and 28A, the two light receiving sections 27B and 28B, and the sensor support member 31 in the front-rear direction (X direction). Normally, the light projecting sections 27A and 28A and the light receiving sections 27B and 28B are on standby at standby positions (see FIG. 6). Then, when mapping is performed, the sensor moving section 29 causes the light projecting sections 27A and 28A and the light receiving sections 27B and 28B to enter the carrier C that is placed on the stage 9 (see FIG. 7).

In a case where the light projecting sections 27A and 28A and the light receiving sections 27B and 28B are located at detection positions, the light projecting sections 27A and 28A and the light receiving sections 27B and 28B are arranged as follows. That is, the light projecting section 27A and the light receiving section 27B of the first mapping sensor 27 are arranged to face each other via a first measurement point MP1, which is set on a straight line LNE so as to be between a center CT and an edge ED of a substrate W1, in plan view. The light projecting section 28A and the light receiving section 28B of the second mapping sensor 28 are arranged to face each other via a second measurement point MP2, which is set on the straight line LNE so as to be between the first measurement point MP1 and the edge ED, in plan view. A distance between the edge ED and the second measurement point MP2 is, for example, 5 mm. Further, a distance between the edge ED and the first measurement point MP1 is, for example, 30 mm to 50 mm.

As illustrated in FIG. 7, the straight line LNE extends, along the loading/unloading direction TD, toward the opening 14 from the center CT of the substrate W1 (W) among the plurality of substrates W that are accommodated in the carrier C. The optical axis LT2 extending from the light projecting section 28A toward the light receiving section 28B crosses a peripheral portion of the substrate W in plan view. Further, the optical axis LT1 crosses the substrate W on a center CT side relative to the optical axis LT2, in plan view.

Note that the load port 5, or the load port 5 and the transfer robot IR correspond to a substrate transfer apparatus of an embodiment of the present invention. The shutter lifting/lowering section 23 corresponds to a lifting/lowering section of an embodiment of the present invention. The first mapping sensor 27 corresponds to a first mapping sensor of an embodiment of the present invention. The second mapping sensor 28 corresponds to a second mapping sensor of an embodiment of the present invention. The light projecting section 27A corresponds to a first light projecting section of an embodiment of the present invention, and the light projecting section 28A corresponds to a second light projecting section of an embodiment of the present invention. Further, the light receiving section 27B corresponds to a first light receiving section of an embodiment of the present invention, and the light receiving section 28B corresponds to a second light receiving section of an embodiment of the present invention. The optical axis LT1 corresponds to a first optical axis. The optical axis LT2 corresponds to a second optical axis.

The substrate processing apparatus 1 may detect the arrangement state of the substrates W in the carrier C, by a method other than mapping with use of the first mapping sensor 27 and the second mapping sensor 28. For example, the substrate processing apparatus 1 may detect the arrangement state of the substrates W by a camera that captures an image of the substrates W in the carrier C.

Reference is made to FIGS. 1, 4, and 8. Next, the following description will discuss the transfer robot IR. The transfer robot IR is placed in the housing 7. The transfer robot IR transfers substrates W between a substrate placement section PS (which will be described later) and three carriers C on the three load ports 5. As the transfer robot IR, for example, a horizontal articulated robot is used. The transfer robot IR includes a plurality of hands 41, an articulated arm 43, a lifting/lowering base 45, and a height sensor 47.

The hands 41 are each a part for taking out a substrate W in the carrier C. The hand 41 holds the substrate W that is in the horizontal orientation. The transfer robot IR uses the hands 41 to take out substrates W from the carrier C that is placed on the stage 9, and also to put substrates W in the carrier C.

The hand 41 is connected to a distal end of the articulated arm 43. The articulated arm 43 has a proximal end that is connected to the lifting/lowering base 45 so as to be rotatable around a vertical axis. The articulated arm 43 moves the hand 41 in the horizontal direction (XY direction). In addition, the articulated arm 43 can change an orientation of the hand 41. The lifting/lowering base 45 moves the hand 41 and the articulated arm 43 in the vertical direction (Z direction). The articulated arm 43 and the lifting/lowering base 45 each include an electric motor. The height sensor 47 measures a height position of the hand 41. The height sensor 47 includes, for example, a rotary encoder or a linear encoder.

In FIG. 8, the transfer robot IR includes four hands 411, 412, 413, and 414 as the hands 41. However, the number of hands 41 which are included in the transfer robot IR may be 3 or less or 5 or more.

The lifting/lowering base 45 integrally moves the hands 411 to 414. In other words, movement caused by the lifting/lowering base 45 does not change a pitch between the hands 411 to 414.

Each of the hands 41 has abutting parts 42 that each abut on a substrate W in a state of holding the substrate W. The abutting parts 42 each have an anti-slip function for preventing the substrate W held by the hand 41 from slipping off.

The transfer robot IR further includes a plurality of brackets 44 that respectively support the hands 41, and a linear guide 46 that supports the brackets 44 such that the brackets 44 are movable in the vertical direction. The linear guide 46 includes an inter-hand pitch measurement section 48 for measuring an inter-hand pitch, which is a pitch between the hands 41.

The inter-hand pitch measurement section 48 may be, for example, a linear encoder. In this case, the inter-hand pitch measurement section 48 can measure a displacement amount of the hand 41 from an origin height which is set for each of the plurality of hands 41. Since origin heights of the plurality of hands 41 are known, the inter-hand pitch measurement section 48 can also measure the inter-hand pitch by measuring displacement amounts from the origin heights. In the following description, it is assumed that the inter-hand pitch measurement section 48 is a linear encoder. However, the inter-hand pitch measurement section 48 is not limited to a linear encoder.

Reference is made to FIGS. 9 and 10. The transfer robot IR further includes a plurality of inter-hand pitch adjustment sections 49 corresponding to each of the plurality of hands 41. In FIGS. 9 and 10, HS1 is the origin height of the hand 411, and HS2 is the origin height of the hand 412. For simplicity, some of the hands 41 are omitted in FIGS. 9 and 10. In addition, the linear guide 46 is omitted in FIG. 10.

The inter-hand pitch adjustment sections 49 each adjust the inter-hand pitch, which is the pitch between the hands 41. In FIG. 9, two inter-hand pitch adjustment sections 49 correspond to one hand 41. However, the number of inter-hand pitch adjustment sections 49 corresponding to one hand 41 may be 1, or 3 or more. The inter-hand pitch adjustment section 49 includes a cylinder 49A, a drive shaft 49B, and a driven shaft 49C.

The cylinder 49A is a cylindrical member which has a piston 49D that is movable inside the cylinder 49A. The cylinder 49A is arranged such that a moving direction of the piston 49D is the front-rear direction. The drive shaft 49B is parallel to the front-rear direction and moves integrally with the piston 49D. The driven shaft 49C is parallel to the vertical direction and moves in accordance with movement of the drive shaft 49B.

The driven shaft 49C is fixed at a position in the horizontal direction. Further, the driven shaft 49C has an inclined groove 49E that is inclined with respect to a horizontal plane. The drive shaft 49B has a pin 49F that is fit into the inclined groove 49E and that is displaceable along the inclined groove 49E. Therefore, as the piston 49D and the drive shaft 49B move in the front-rear direction, the driven shaft 49C moves in the vertical direction.

The driven shaft 49C is attached to the bracket 44. Therefore, by moving the piston 49D in the front-rear direction in the cylinder 49A, it is possible to change the height of the hand 41 which is supported by the bracket 44.

Air may be supplied to the cylinder 49A via a proportional control valve (not illustrated). The proportional control valve is a solenoid valve in which a flow rate of air changes in proportion to an electric current. A movement amount of the bracket 44 is represented by pulse count from the inter-hand pitch measurement section 48, which is a linear encoder. By inputting, to the proportional control valve, a current corresponding to a target value of the pulse count, it becomes possible to control inflow or outflow of air into or from the cylinder 49A and move the piston 49D and the bracket 44 by the target value. This makes it possible to separately adjust the displacement amount of the hand 411 from the origin height HS1 and the displacement amount of the hand 412 from the origin height HS2.

Note that the inter-hand pitch adjustment section 49 does not necessarily have to include the cylinder 49A, and may instead include, for example, an electric actuator. In this case, the displacement amount of each of the hands 41 from the origin height can be adjusted by moving the driven shaft 49C with use of the electric actuator.

### 1-2. Processing Block

Reference is made to FIG. 1. The processing block 3 includes at least one processing unit 51, a center robot CR, and a substrate placement section (shelf) PS. The substrate placement section PS is provided between the transfer robot IR and the center robot CR. On the substrate placement section PS, one or more substrates W can be placed.

The processing unit 51 performs a preset process on substrates W. The processing unit 51 performs, for example, at least one of an application process for a processing liquid such as a resist, a developing process, a cleaning process, and a polishing (grinding) process.

Note that: in a case where the processing unit 51 performs the cleaning process, the processing unit 51 may include a brush; or in a case where the processing unit 51 performs the polishing (grinding) process, the processing unit 51 may include a polishing tool. Alternatively, the processing unit 51 may perform a dry etching process, an ashing process, or a film forming process.

The center robot CR is configured similarly to the transfer robot IR. Briefly, the center robot CR includes a hand 61 that holds a substrate W in the horizontal orientation. The center robot CR moves the hand 61 holding a substrate W in the horizontal direction (XY direction) and the vertical direction (Z direction). Further, the center robot CR changes an orientation of the hand 61 around the vertical axis. The center robot CR transfers the substrate W between at least one processing unit 51 and the substrate placement section PS. Note that the center robot CR and/or the transfer robot IR may include, instead of the articulated arm, for example, an advancing/retreating section which has a screw shaft and a guide rail. This advancing/retreating section advances and retreats the hand.

### 1-3. Control

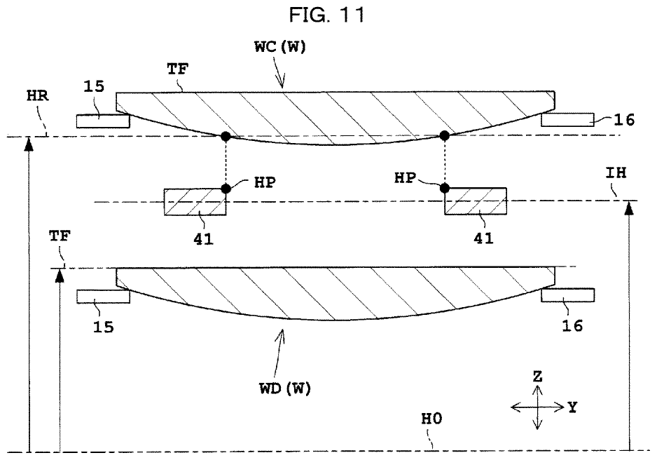

The substrate processing apparatus 1 further includes a controller (control section) 71 and a memory (storage section) 73. The controller 71 controls each constituent element of the substrate processing apparatus 1. The controller 71 includes at least one processor such as a central processing unit (CPU). The controller 71 calculates hand entry positions IH (see FIG. 11) which the hands 41 should be made to enter, on the basis of the arrangement state of the plurality of substrates W which have been detected by the first mapping sensor 27 and the second mapping sensor 28. In addition, the controller 71 controls the inter-hand pitch adjustment section 49 such that the plurality of hands 41 included in the transfer robot IR respectively enter a plurality of hand entry positions IH. This allows the substrate processing apparatus 1 to optimize the pitch between the hands 41 in accordance with the arrangement state of the substrates W.

Specifically, the controller 71 calculates each difference between (i) an inter-hand-entry-position pitch, which is a pitch between the hand entry positions IH, and (ii) the inter-hand pitch which has been measured by the inter-hand pitch measurement section 48. Furthermore, the controller 71 controls the inter-hand pitch adjustment section 49 such that all of the differences calculated are less than or equal to a predetermined threshold value.

FIG. 11 is a diagram illustrating an example of a method for calculating a hand entry position IH. The hand entry position IH is a height position that takes into account warpage shapes of substrates W. FIG. 11 is a diagram for explaining the method for calculating the hand entry position IH of a hand 41 that is to be inserted between two vertically adjacent substrates WC and WD. In FIG. 11, the substrates WC and WD are warped such that a central portion is lower than an outer edge portion. A point on the hand 41 that comes into contact with the substrate WC when the substrate WC is taken out is referred to as a contact point HP. Further, the height position of the substrate WC at a position where the contact point HP comes into contact with the substrate WC is referred to as a warpage height position HR. In addition, in FIG. 11, the reference sign H0 indicates that the height position is 0 (zero). The controller 71 calculates the hand entry position IH of the hand 41 between the substrate WC and the substrate WD, by the following formula (1).

$$\\ \begin{matrix}Hand entry position IH = ( warpage height position HR of substrate WC + height position TF of upper surface of substrate WD ) / 2 & ( 1 )\end{matrix}$$

Clearance between each of the substrates WC and WD and the hand 41 becomes maximum at the hand entry position IH calculated by the formula (1). The clearance which is referred to here is a distance between the hand 41 and one of the substrates WC and WD that is closer to the hand 41. That is, the clearance becoming maximum means that smaller one of the distance between the substrate WC and the hand 41 and the distance between the substrate WD and the hand 41 becomes maximum.

The controller 71 controls the inter-hand pitch adjustment section 49 so as to cause the hand 41 to enter the hand entry position IH. Therefore, the substrate processing apparatus 1 can optimize the pitch between the hands 41 in accordance with the arrangement state of the substrates W.

### (Repetition of Transfer Operation)

In an example illustrated in FIG. 3, the number of substrates W that are accommodated in the carrier C is 25. On the other hand, in the example illustrated in FIG. 4, the number of hands 41 included in the transfer robot IR is 4. The number of hands 41 is not limited to this. In many cases, the number of hands 41 included in the transfer robot IR in the substrate processing apparatus 1 is generally smaller than the number of substrates W that are accommodated in the carrier C at the time when the carrier C is placed on the stage 9.

The controller 71 determines, among the plurality of substrates W in the carrier C, which substrates W are to be transferred in a batch by the plurality of hands 41 that are included in the transfer robot IR. Furthermore, the controller 71 transfers all the substrates W in the carrier C by (i) switching the substrates W that are to be transferred every time a single transfer operation completes and (ii) repeating the transfer operation. This allows the controller 71 to sequentially transfer all the substrates W in the carrier C.

The arrangement state of the substrates W which the controller 71 detects with use of the first mapping sensor 27 and the second mapping sensor 28 includes the number of substrates W in the carrier C. The controller 71 can determine whether or not there is any substrate W in the carrier C after completion of a transfer operation, on the basis of the number of substrates W in the carrier C and the number of substrates W which are transferred in a single transfer operation. The controller 71 repeats the transfer operation, in a case where there is a substrate W in the carrier C after the completion of the transfer operation.

In a case where the transfer operation is repeated, it is conceivable that even when the inter-hand pitch is returned to an initial value after the end of a transfer operation, re-adjustment of the inter-hand pitch may become necessary in a next transfer operation. In such a case, adjustment for returning the inter-hand pitch to the initial value after the end of the transfer operation may be wasted.

For this reason, in a case where the transfer operation is repeated, the controller 71 may control the inter-hand pitch adjustment section 49 such that, at a timing of switching the transfer operation, the plurality of hands 41 included in the transfer robot IR respectively enter the hand entry positions in the next transfer operation, without returning the inter-hand pitch to the initial value. This allows the controller 71 to omit the adjustment of the inter-hand pitch that may be wasted, and to promptly perform the next transfer operation.

A memory 73 includes, for example, at least one of a read-only memory (ROM), a random-access memory (RAM), and a hard disk. The memory 73 stores a computer program that is necessary for controlling each configuration of the substrate processing apparatus 1. Further, the memory 73 stores various operations (for example, steps S1 to S15 and S151 to S157, which will be described later). Note that the substrate processing apparatus 1 does not necessarily have to include the memory 73, and may be connected to an external storage device that stores the above-described information so as to be capable of communicating with the external storage device.

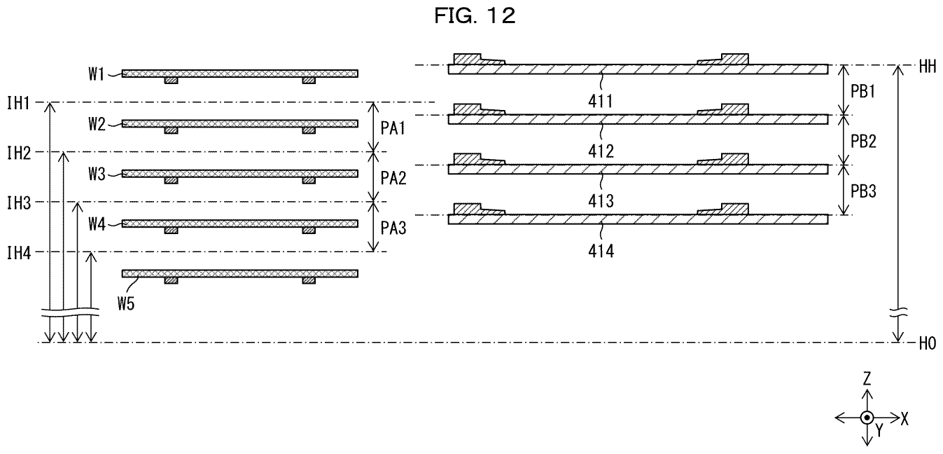

FIG. 12 is a diagram illustrating an example operation of the transfer robot IR. In FIG. 12, five substrates W1 to W5 are arranged in order from the top. The following description will discuss an example in which four of these substrates W1 to W4 are taken out by the transfer robot IR with use of the four hands 411 to 414.

First, the controller 71 measures respective positions and thicknesses of the substrates W1 to W5. Next, the controller 71 calculates optimal hand entry positions IH1 to IH4 for inserting the hands 41, in order to take out each of the substrates W1 to W4.

The controller 71 calculates pitches PA1 to PA3 between two adjacent ones of the hand entry positions IH1 to IH4. Further, the controller 71 calculates pitches PB1 to PB3 between two adjacent ones of the hands 411 to 414. Then, the controller 71 individually adjusts respective heights of the hands 411 to 414 by the inter-hand pitch adjustment section 49 so that the difference between the pitches PA1 and PB1, the difference between the pitches PA2 and PB2, and the difference between the pitches PA3 and PB3 are all less than or equal to a threshold value. The threshold value may be set in consideration of the pitches between the substrates W in design of the carrier C, the thicknesses of the substrates W, and the like, and is, for example, 0.1 mm or 0.05 mm.

In a state in which respective differences between the pitches PA1 and PB1, the pitches PA2 and PB2, the pitches PA3 and PB3, and the pitches PB4 and PB4 have become less than or equal to the threshold value, the controller 71 integrally moves the hands 411 to 414 by the lifting/lowering base 45 so as to align the position HH of the hand 411 with the hand entry position IH1. As a result, the hands 412 to 414 also move to the hand entry positions IH2 to IH4, respectively.

### (Teaching and Calibration Process)

As described above, the linear guide 46 includes the inter-hand pitch measurement section 48 that is capable of measuring the displacement amount of each of the plurality of hands 41 from the origin height. Accordingly, in order to measure the inter-hand pitch with use of the inter-hand pitch measurement section 48, it is necessary to perform, prior to the start of use of the transfer robot IR, teaching with regard to the origin height of each of the plurality of hands 41 in the inter-hand pitch measurement section 48.

An optical measurement section 65 is used for the teaching with regard to the origin height. The optical measurement section 65 optically measures the inter-hand pitch. As illustrated in FIG. 1, the optical measurement section 65 is arranged, for example, on an upper side of the substrate placement section PS. The optical measurement section 65 includes a light projecting section 65A and a light receiving section 65B.

The light projecting section 65A emits light L toward the light receiving section 65B. The light L is band-shaped light having a width direction in the vertical direction, that is, a direction perpendicular to the paper surface in FIG. 1. The light receiving section 65B receives the light L emitted from the light projecting section 65A.

In the teaching, the controller 71 inserts the plurality of hands 41 between the light projecting section 65A and the light receiving section 65B. At that time, at respective heights where the plurality of hands 41 are present, the light L is not received by the light receiving section 65B. Therefore, the controller 71 can measure the respective heights of the plurality of hands 41 on the basis of the heights at which the light L was not received by the light receiving section 65B.

The controller 71 inserts each of the plurality of hands 41 between the light projecting section 65A and the light receiving section 65B so that the heights at two positions in the horizontal direction are measured. For example, as illustrated in FIG. 8, the positions of the two abutting parts 42 in the front-rear direction are defined as a first position PM1 and a second position PM2. The controller 71 controls the transfer robot IR such that the first position PM1 and the second position PM2 are arranged in this order between the light projecting section 65A and the light receiving section 65B. The controller 71 regards, for each of the plurality of hands 41, an average value of the heights at the two positions in the horizontal direction as the height of the hand 41. Note that the controller 71 may insert each of the plurality of hands 41 between the light projecting section 65A and the light receiving section 65B so as to measure heights at three or more positions in the horizontal direction.

The controller 71 corrects a measurement output value from the inter-hand pitch measurement section 48, on the basis of a result of measurement by the optical measurement section 65. Specifically, in the teaching, the controller 71 performs an adjustment so that all differences between (i) each of the pitches between respective average heights of the hands 411 to 414 and (ii) a predetermined pitch (for example, 10 mm) are less than or equal to a threshold value (for example, 0.1 mm or 0.05 mm). The controller 71 adjusts the pitch between the hands 41 with use of the inter-hand pitch adjustment section 49, with reference to the pulse count from the inter-hand pitch measurement section 48, which is a linear encoder. This allows the controller 71 to measure, for each of the plurality of hands 41, the inter-hand pitch by setting the height after the adjustment as the origin and measuring the displacement amount with use of the inter-hand pitch measurement section 48.

Further, even in a case where the teaching is performed prior to the start of use of the transfer robot IR, the origin height of the hand 41 in the inter-hand pitch measurement section 48 may change due to deterioration or the like accompanying the use of the transfer robot IR. For this reason, the controller 71 may perform a calibration process on the origin height in the same manner as the teaching under a certain condition, after the start of use of the transfer robot IR. Examples of the certain condition include transfer of a certain number of lots of substrates W or transfer of a certain number of substrates W, or elapse of a certain period.

### (Substrate Transfer Method)

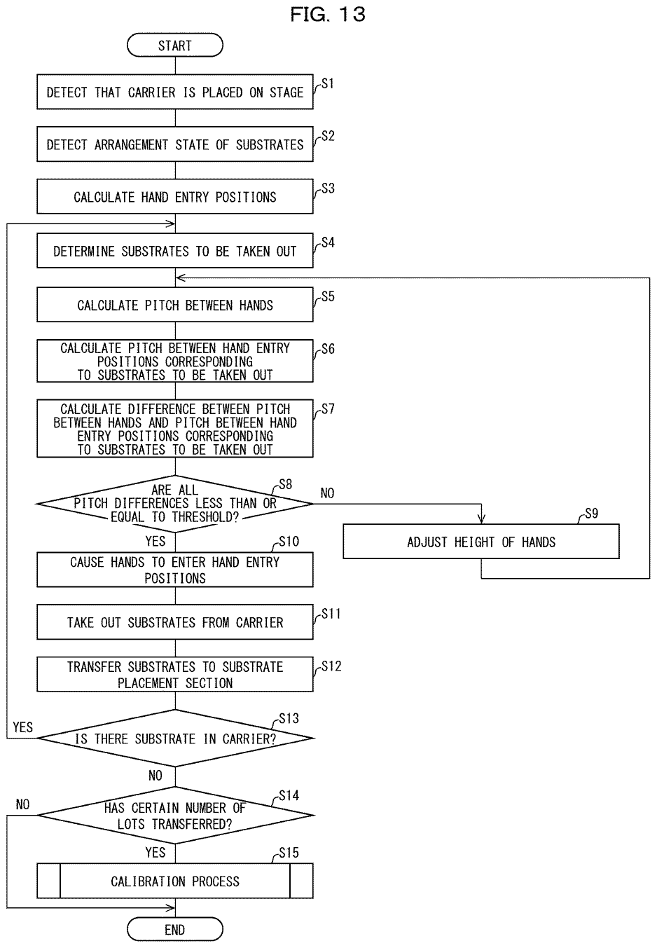

FIG. 13 is a flowchart illustrating an example of a substrate transfer method in the substrate processing apparatus 1. In a case where the carrier C is placed on the stage 9 of any one of the load ports 5, the controller 71 detects this by the load presence sensor which is provided on the stage 9 (S1). Upon detecting that the carrier C has been placed on the stage 9, the controller 71 detects the arrangement state of the substrates W in the carrier C with use of the first mapping sensor 27 and the second mapping sensor 28 (S2). Furthermore, the controller 71 calculates a hand entry position which the hand 41 should be caused to enter in order to take out each of the substrates W, on the basis of the arrangement state of the substrates W (S3).

Further, the controller 71 determines, from among the substrates W accommodated in the carrier C, substrates W that are to be taken out by a single operation of the transfer robot IR (S4). The controller 71 calculates a pitch for the plurality of hands 41 (S5) and also calculates a pitch between the hand entry positions corresponding to the substrates W that are to be taken out (S6).

The controller 71 calculates a difference between the pitch between the hands 41 and the pitch between the hand entry positions corresponding to the substrates W that are to be taken out (S7). Furthermore, the controller 71 determines whether or not all pitch differences that have been calculated in step S7 are less than or equal to a threshold value (S8). In a case where one or more of the pitch differences calculated in step S7 are more than the threshold value (NO in S8), the controller 71 controls the inter-hand pitch adjustment section 49 and adjusts the height of the hands 41 so as to make the one or more differences less than or equal to the threshold value (S9). That is, the controller 71 controls the inter-hand pitch adjustment section 49 so that the plurality of hands 41 included in the transfer robot IR respectively enter the hand entry positions. Thereafter, the controller 71 repeats processing from step S5.

In a case where all of the pitch differences calculated in step S7 are less than or equal to the threshold value (YES in S8), the controller 71 causes the hands 41 to enter the hand entry positions corresponding to the substrates W to be taken out (S10), and takes out the substrates W from the carrier C (S11). Furthermore, the controller 71 transfers, to the substrate placement section PS, the substrates W that have been taken out from the carrier C by the hands 41 (S12).

After step S12, the controller 71 determines whether or not there is any substrate W in the carrier C (S13). In a case where there is a substrate W in the carrier C (YES in S13), the controller 71 repeats the processing from step S4. In a case where there is no substrate W in the carrier C (NO in S13), the controller 71 determines whether or not a certain number of lots of substrates W have been transferred (S14). In a case where the certain number of lots of substrates W have been transferred (YES in S14), the controller 71 executes the calibration process for the origin height in the inter-hand pitch measurement section 48 (S15). The content of the calibration process will be described later. After the calibration process, the controller 71 ends the processing. On the other hand, in a case where the certain number of lots of substrates W have not yet been transferred (NO in S14), the controller 71 skips the calibration process and ends the processing.

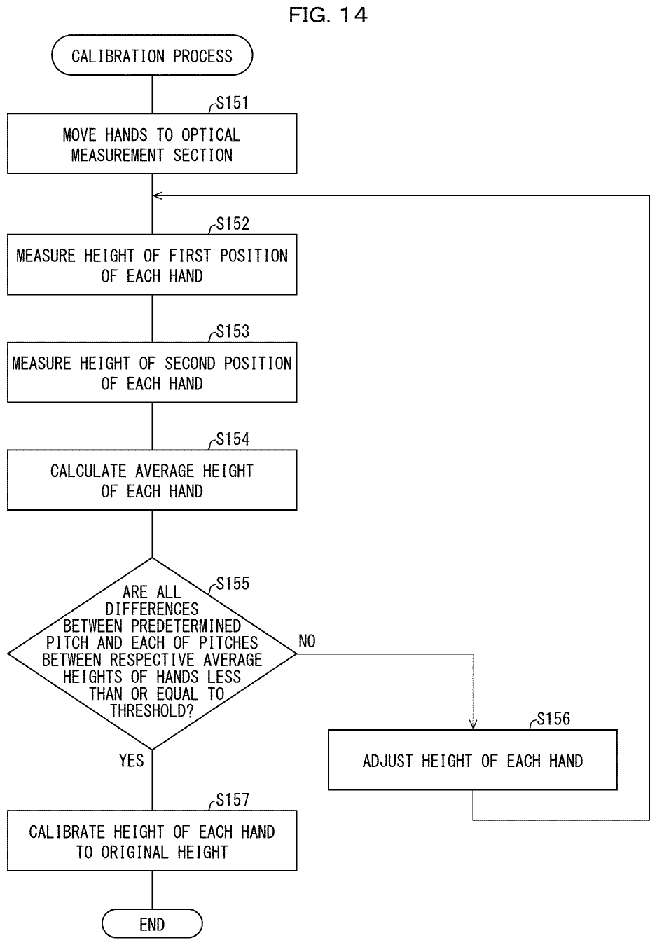

FIG. 14 is a flowchart illustrating an example of the calibration process. In the calibration process, the controller 71 moves the hands 41 to the optical measurement section 65 (S151). The controller 71 measures the height of the first position PM1 of each of the hands 41 (S152), and further measures the height of the second position PM2 (S153). Then, the controller 71 calculates an average of the heights of the first position PM1 and the second position PM2 for each of the hands 41 (S154).

The controller 71 determines whether or not all differences between (i) each of pitches between respective average heights of the hands 41 and (ii) a predetermined pitch are less than or equal to a threshold value (S155). In a case where there is a difference that is more than the threshold value between (i) any of the pitches of the respective average heights of the hands 41 and (ii) the predetermined pitch (NO in S155), the controller 71 adjusts the height of each of the hands 41 so that the difference between those pitches becomes less than or equal to the threshold value (S156). Thereafter, the controller 71 repeats the processing from step S152. In a case where all of the differences between (i) each of the pitches of the respective average heights of the respective hands 41 and (ii) the predetermined pitch are less than or equal to the threshold value (YES in S155), the controller 71 calibrates the height of each of the hands 41 to the origin height corresponding to that hand 41 in the inter-hand pitch measurement section 48 (S157). The calibration process is thus completed.

Aspects of the present invention can also be expressed as follows:
A substrate transfer system according to an aspect of the present invention includes: a substrate transfer mechanism including a plurality of hands for taking out a plurality of substrates from a transfer container which carries the plurality of substrates during transfer, in a state in which the plurality of substrates are accommodated in a shelf-like manner, and an inter-hand pitch adjustment section that adjusts each inter-hand pitch, which is a pitch between the plurality of hands; a substrate detection section that detects an arrangement state of the plurality of substrates in the transfer container; and a controller, said substrate transfer system taking out the plurality of substrates from the transfer container and transferring the plurality of substrates, by the substrate transfer mechanism, the controller calculating a plurality of hand entry positions which the hands are caused to enter, on the basis of the arrangement state of the plurality of substrates that is detected by the substrate detection section, and the controller controlling the inter-hand pitch adjustment section so that the plurality of hands provided in the substrate transfer mechanism respectively enter the plurality of hand entry positions.

The substrate transfer system according to an aspect of the present invention further includes an inter-hand pitch measurement section that measures the inter-hand pitch in the substrate transfer mechanism, the controller calculating a plurality of differences between the inter-hand pitch and an inter-hand-entry-position pitch that is a pitch between the plurality of hand entry positions which the plurality of hands provided in the substrate transfer mechanism are to be respectively inserted, and controlling the inter-hand pitch adjustment section so that all of the differences are less than or equal to a predetermined threshold.

In the substrate transfer system according to an aspect of the present invention: the inter-hand pitch measurement section is a linear encoder; and the controller controls the inter-hand pitch adjustment section on the basis of output from the linear encoder.

The substrate transfer system according to an aspect of the present invention further includes an optical measurement section that optically measures the inter-hand pitch, the controller correcting a measurement output value outputted by the linear encoder, on the basis of a result of measurement performed by the optical measurement section.

In the substrate transfer system according to an aspect of the present invention, the controller determines, among the plurality of substrates in the transfer container, substrates to be transferred in a batch by the plurality of hands provided in the substrate transfer mechanism, and transfers all the plurality of substrates from the transfer container by (i) switching the substrates to be transferred every time a single transfer operation is completed and (ii) repeating the transfer operation.

In the substrate transfer system according to an aspect of the present invention, when repeating the transfer operation, the controller controls the inter-hand pitch adjustment section such that: the inter-hand pitch does not return to an initial value at a timing of switching the transfer operation; and the plurality of hands provided in the substrate transfer mechanism respectively enter the hand entry positions in the transfer operation to be performed next.

Further, a substrate transfer method according to an aspect of the present invention is a method for a substrate transfer system, the substrate transfer system including: a substrate transfer mechanism including a plurality of hands for taking out a plurality of substrates in a transfer container which carries the plurality of substrates during transfer, in a state in which the plurality of substrates are accommodated in a shelf-like manner, and an inter-hand pitch adjustment section that adjusts each inter-hand pitch, which is a pitch between the plurality of hands; and a substrate detection section that detects an arrangement state of the plurality of substrates in the transfer container, the substrate transfer system taking out the plurality of substrates from the transfer container and transferring the plurality of substrates, by the substrate transfer mechanism, said substrate transfer method including: calculating hand entry positions which the hands are caused to enter, on the basis of the arrangement state of the plurality of substrates that is detected by the substrate detection section; and controlling the inter-hand pitch adjustment section so that the plurality of hands provided in the substrate transfer mechanism respectively enter the hand entry positions.

### REFERENCE SIGNS LIST

1 substrate processing apparatus (substrate transfer system)
27 first mapping sensor (substrate detection section)
28 second mapping sensor (substrate detection section)
41, 411, 412, 413, 414 hand
48 inter-hand pitch measurement section (linear encoder)
49 inter-hand pitch adjustment section
65 optical measurement unit
71 controller (control unit)
IR transfer robot (substrate transfer mechanism)

1. A substrate transfer system comprising:
a substrate transfer mechanism including
a plurality of hands for taking out a plurality of substrates from a transfer container which carries the plurality of substrates during transfer, in a state in which the plurality of substrates are accommodated in a shelf-like manner, and
an inter-hand pitch adjustment section that adjusts each inter-hand pitch, which is a pitch between the plurality of hands;
a substrate detection section that detects an arrangement state of the plurality of substrates in the transfer container; and
a controller,
said substrate transfer system taking out the plurality of substrates from the transfer container and transferring the plurality of substrates, by the substrate transfer mechanism,
the controller calculating a plurality of hand entry positions which the hands are caused to enter, on the basis of the arrangement state of the plurality of substrates that is detected by the substrate detection section, and
the controller controlling the inter-hand pitch adjustment section so that the plurality of hands provided in the substrate transfer mechanism respectively enter the plurality of hand entry positions.

2. The substrate transfer system according to claim 1, further comprising
an inter-hand pitch measurement section that measures the inter-hand pitch in the substrate transfer mechanism,
the controller calculating a plurality of differences between the inter-hand pitch and an inter-hand-entry-position pitch that is a pitch between the plurality of hand entry positions which the plurality of hands provided in the substrate transfer mechanism are to be respectively inserted, and controlling the inter-hand pitch adjustment section so that all of the differences are less than or equal to a predetermined threshold.

3. The substrate transfer system according to claim 2, wherein:
the inter-hand pitch measurement section is a linear encoder; and
the controller controls the inter-hand pitch adjustment section on the basis of output from the linear encoder.

4. The substrate transfer system according to claim 3, further comprising
an optical measurement section that optically measures the inter-hand pitch,
the controller correcting a measurement output value outputted by the linear encoder, on the basis of a result of measurement performed by the optical measurement section.

5. The substrate transfer system according to claim 1, wherein the controller determines, among the plurality of substrates in the transfer container, substrates to be transferred in a batch by the plurality of hands provided in the substrate transfer mechanism, and transfers all the plurality of substrates from the transfer container by (i) switching the substrates to be transferred every time a single transfer operation is completed and (ii) repeating the transfer operation.

6. The substrate transfer system according to claim 5, wherein, when repeating the transfer operation, the controller controls the inter-hand pitch adjustment section such that: the inter-hand pitch does not return to an initial value at a timing of switching the transfer operation; and the plurality of hands provided in the substrate transfer mechanism respectively enter the hand entry positions in the transfer operation to be performed next.

7. A substrate transfer method for a substrate transfer system,
the substrate transfer system including:
a substrate transfer mechanism including
a plurality of hands for taking out a plurality of substrates in a transfer container which carries the plurality of substrates during transfer, in a state in which the plurality of substrates are accommodated in a shelf-like manner, and
an inter-hand pitch adjustment section that adjusts each inter-hand pitch, which is a pitch between the plurality of hands; and
a substrate detection section that detects an arrangement state of the plurality of substrates in the transfer container,
the substrate transfer system taking out the plurality of substrates from the transfer container and transferring the plurality of substrates, by the substrate transfer mechanism,
said substrate transfer method comprising:
calculating hand entry positions which the hands are caused to enter, on the basis of the arrangement state of the plurality of substrates that is detected by the substrate detection section; and
controlling the inter-hand pitch adjustment section so that the plurality of hands provided in the substrate transfer mechanism respectively enter the hand entry positions.
